(19) United States
(12) Patent Application Publication
(10) Pub. No.: US 2007/0241438 A1
(43) Pub. Date: Oct. 18, 2007

(54) Strip format of package board and array of the same

(75) Inventors: Tae Hyeog Kang, Chungcheongbuk-do (KR); Kwang Seop Youm, Chungcheongbuk-do (KR); Kyu Hyun Shim, Daejeon (KR); Bong Kyu Choi, Chungcheongbuk-do (KR); Kyu Il Hwang, Chungcheongbuk-do (KR); Won Hee Kim, Chungcheongbuk-do (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 11/783,874

(22) Filed: Apr. 12, 2007

(30) Foreign Application Priority Data
Apr. 12, 2006 (KR) 10-2006-0033266

(51) Int. Cl. H01L 23/02

(52) U.S. Cl. 257/678

(57) ABSTRACT

Disclosed herein is a strip format of a semiconductor package board and an array thereof, in which a dummy area of the strip format of the semiconductor package board is formed into a predetermined shape such that, when several strip formats of semiconductor package boards are arranged on a panel, the number of strip formats of semiconductor package boards arranged on the panel can be increased.

### CROSS REFERENCE TO RELATED APPLICATION

This application claims the benefit of Korean Patent Application No. 10-2006-0033266, filed Apr. 12, 2006, entitled “A PACKAGE STRIP FORMAT AND ITS ARRAY”, which is hereby incorporated by reference in its entirety into this application.

### BACKGROUND OF THE INVENTION

1. Field of the Invention

The present invention relates generally to strip formats of semiconductor package boards and arrays thereof and, more particularly, to a strip format of a semiconductor package board and an array thereof in which a dummy area of the strip format of the semiconductor package board is formed into a predetermined shape such that, when several strip formats of semiconductor package boards are arranged on a panel, the number of strip formats of semiconductor package boards arranged on the panel can be increased.

2. Description of the Related Art

As well known to those skilled in the art, the conventional strip format of a semiconductor package board has the construction shown in FIG. 1.

The construction of the conventional strip format of the semiconductor package board will be explained in detail herein below with reference to FIG. 1. Typically, the strip format 10 of the semiconductor package board includes a semiconductor package area 11, which has a semiconductor device mounting part 11a and an outer layer circuit pattern 11b, and a dummy area 12, which surrounds the semiconductor package area 11.

A plurality of strip formats 10 of semiconductor package boards having the above-mentioned constructions is arranged on a panel. Here, each strip format 10 of the semiconductor package board has a predetermined standard size. The panel also has a predetermined standard size. Therefore, the number of semiconductor package boards that can be mounted to the panel is set at a predetermined value.

The arrangement of strip formats of semiconductor package boards on the panel is shown in FIG. 2. Referring to FIG. 2, a predetermined number of strip formats 10 of semiconductor package boards is arranged on the panel 20.

That is, in this drawing, ten strip formats 10 of semiconductor package boards are arranged on the panel 20. As such, it will be appreciated that, because the shape of the strip format 10 of each semiconductor package board and the shape of the panel 20 are standardized, the number of strip formats 10 of semiconductor package boards that can be mounted to the panel 20 is fixed at a predetermined value.

Therefore, in a conventional process of assembling semiconductor package boards, because the standard sizes of the strip format of the semiconductor package board and the panel are maintained constant, no effort to increase the number of strip formats of semiconductor package boards that can be mounted to the panel has been attempted. However, to respond to the trend of decreasing process duration and improving process efficiency in the process of manufacturing the semiconductor package board, the limitation of the number of strip formats of semiconductor package boards that can be mounted to the panel must be overcome.

### SUMMARY OF THE INVENTION

Accordingly, the present invention has been made keeping in mind the above problems occurring in the prior art, and an object of the present invention is to provide a strip format of a semiconductor package board and an array thereof in which a dummy area is formed into a predetermined shape such that, when several strip formats are arranged on a panel, the number of strip formats arranged on the panel can be increased compared to the conventional art.

Another object of the present invention is to provide a strip format of a semiconductor package board and an array thereof in which the coupling relationship between strip formats is improved, because the dummy areas of the strip formats are formed into the above-mentioned shapes.

In an aspect, the present invention provides a strip format of a semiconductor package board, including: a package area, to which a semiconductor device is mounted, with an outer layer circuit pattern formed in the package area; and a dummy area surrounding the package area. The dummy area is formed into a predetermined shape to improve a coupling relationship between the strip format and another strip format.

The shape of the dummy area may be defined by prominence and depression parts having various shapes such that the strip formats engage each other.

In another aspect, the present invention provides a panel array for arranging strip formats of semiconductor package boards, including: a plurality of strip formats of semiconductor package boards, each of the strip formats comprising a package area to which a semiconductor device is mounted, with an outer layer circuit pattern formed in the package area, and a dummy area surrounding the package area and having a predetermined shape; and a panel, on which the plurality of strip formats of the semiconductor package boards are arranged at regular intervals.

The shape of the dummy area of each of the strip formats of the semiconductor package boards may be defined by prominence and depression parts having various shapes such that the strip formats engage with each other.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a perspective view of a conventional strip format of a semiconductor package board;

FIG. 2 is a view showing conventional strip formats of semiconductor package boards arrayed on a panel;

FIG. 3 is a view showing a strip format, according to a first embodiment of the present invention;

FIG. 4 is a view showing the strip formats of FIG. 3 connected to each other;

FIG. 5 is a view showing the strip formats of FIG. 3 arrayed on a panel;

FIG. 6 is a view showing a strip format, according to a second embodiment of the present invention;

FIG. 7 is a view showing the strip formats of FIG. 6 connected to each other; and

FIG. 8 is a view showing the strip formats of FIG. 6 arrayed on a panel.

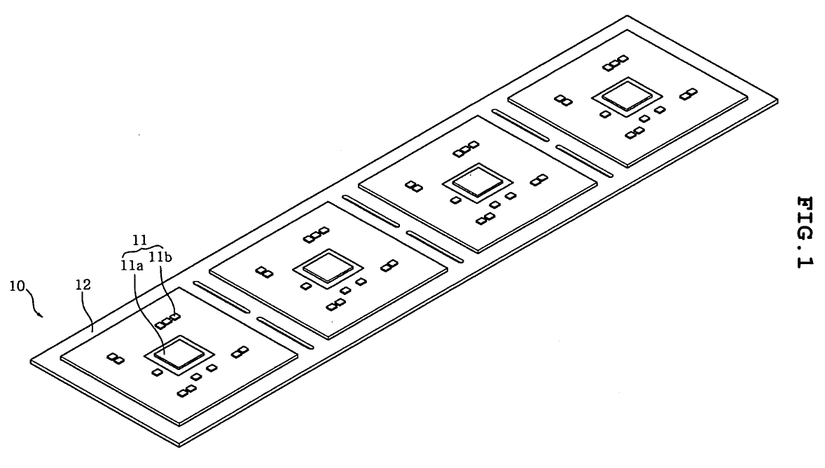

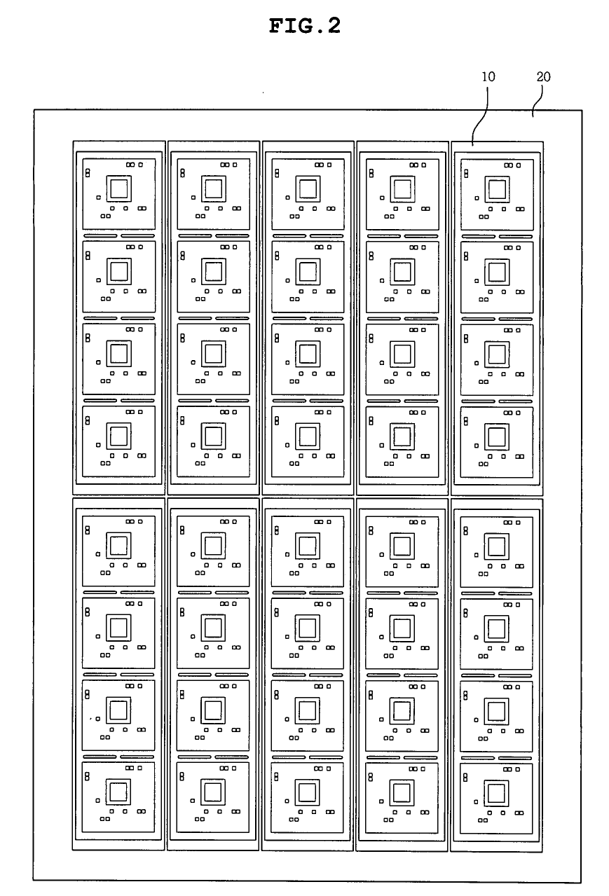

### DESCRIPTION OF THE PREFERRED EMBODIMENTS

Hereinafter, the present invention will be described in detail with reference to the attached drawings.

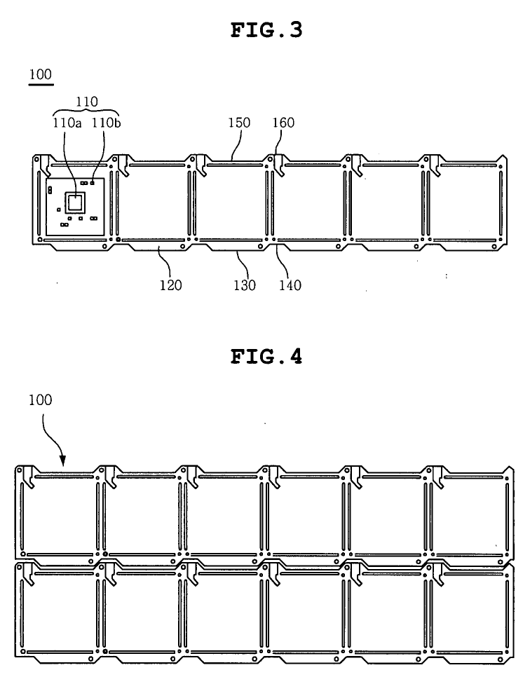

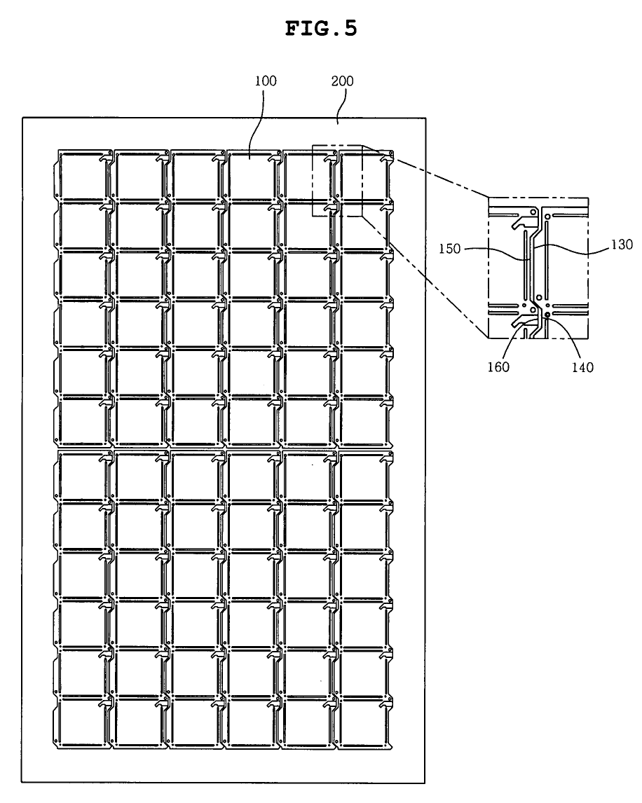

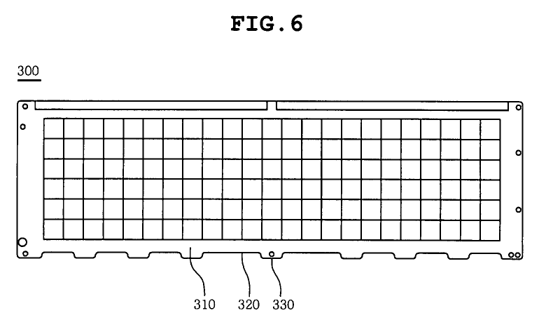

For reference, FIG. 3 illustrates a strip format of a PBGA (plastic ball grid array) semiconductor package board, according to a first embodiment of the present invention. FIG. 4 illustrates the strip formats coupled to each other. FIG. 5 illustrates the strip formats of the PBGA semiconductor package boards which are arrayed on a panel. FIGS. 6 through 8 illustrate the case of use of a CSP (chip-size package) semiconductor package board, according to a second embodiment of the present invention.

As described above, the present invention provides a method of increasing the number of strip formats of semiconductor package boards to be arrayed on a panel. In detail, the present invention is characterized in that the strip format is formed into a predetermined shape such that unnecessary portions are maximally removed from a dummy area provided in the area surrounding the strip format of the semiconductor package board, thus achieving the above-mentioned object. That is, the present invention achieves the above-mentioned object using a technical characteristic in which the dummy area is removed before a package area is mounted to a mother board after a semiconductor device has been mounted to a semiconductor device mounting part.

The strip format of the PBGA semiconductor package board according to the first embodiment of the present invention having the above-mentioned technical characteristic will be explained in detail herein below. The strip format 100 of the semiconductor package board according to the present invention is shown in FIG. 3. As shown in the drawing, the strip format 100 of the semiconductor package board includes a package area 110, which has a semiconductor device mounting part 110a and an outer layer circuit pattern 110b, and a dummy area 120, which surrounds the package area 110, and on which a copper pattern is formed. The dummy area 120 has a predetermined shape which includes prominence parts and depression parts.

Here, the package area 110 is mounted to the mother board or the like in a state in which the dummy area 120 is removed after a semiconductor device has been mounted to and packaged on the semiconductor device mounting part 110a. Furthermore, an inner layer pattern (not shown) as well as the outer layer circuit pattern 110b is formed in the package area 110, so that the package area 110 transmits and receives electrical signals to and from the semiconductor device.

The semiconductor device mounting part 110a is an area for mounting a semiconductor device thereon, and is typically placed on the central portion of the package area 110. Here, the semiconductor device, which is mounted to the semiconductor device mounting part 110a, is electrically connected to a wire bonding pad or a solder ball pad, which is provided on the outer layer circuit pattern 110b. Furthermore, to dissipate heat from the semiconductor device, which is mounted to the semiconductor device mounting part 110a, it is preferable that the semiconductor device mounting part 110a be made of conductive material (for example, copper or gold).

The outer layer circuit pattern 110b is formed around the semiconductor device mounting part 110a. The wire bonding pad or solder ball pad of the outer layer circuit pattern 110b, which is electrically connected to the semiconductor device mounted to the semiconductor device mounting part 110a, is exposed outside a solder resist pattern (not shown).

The dummy area 120 is an area that is removed before the package area 110 is mounted to the mother board or the like after the semiconductor device has been mounted to the semiconductor device mounting part 110a. The dummy area 120 surrounds the package area 110. The present invention is technically characterized in that the dummy area 120 is formed into a predetermined shape. In detail, one edge of the strip format 100, that is, one edge of the dummy area 120, is formed into a shape such that trapezoidal prominence parts 130 and trapezoidal depression parts 140 are alternately arranged. Furthermore, the opposite edge of the strip format 100 is formed into a shape in which trapezoidal depression parts 150 are formed at positions corresponding to the respective trapezoidal prominence parts 130, and trapezoidal prominence parts 160 are formed at positions corresponding to the respective trapezoidal depression parts 140. As such, the strip format 100 of the semiconductor package board of the present invention is technically characterized in that the dummy area 120 is formed into the above-mentioned shape. In the first embodiment, although the prominence parts and the depression parts of the dummy area 120 have been illustrated as having trapezoidal shapes, the present invention is not limited thereto. In other words, their shapes are not limited to any particular shapes as long as they make it possible to smoothly couple strip formats to each other.

The arrangement of the strip formats 100 of the semiconductor package boards having the above-mentioned shapes is shown in FIG. 4. Referring to FIG. 4, two strip formats 100 are arranged such that the prominence parts and the depression parts of the dummy areas 120 thereof are aligned with each other and smoothly engage with each other. Therefore, the height of the strip formats 100 of the semiconductor package boards of the present invention having the above-mentioned arrangement is less than that of the conventional arranged strip formats of the semiconductor package boards. Furthermore, the coupling between the strip formats in the array of the present invention is maintained more stable, compared to the conventional art.

Meanwhile, FIG. 5 shows the strip formats 100 of the semiconductor package boards arranged on the panel 200. As shown in FIG. 5, in the present invention, twelve strip formats 100 of the semiconductor package boards are arranged on the panel 200. That is, compared to the conventional art, in which ten strip formats of semiconductor package boards can be arranged on a panel having the same size as the panel 200 of FIG. 5, the number of strip formats 100 of the semiconductor package boards in the present invention is increased by 20%. As such, it is understood that the above-mentioned object of the present invention can achieved by arranging the strip formats 100 of the semiconductor package boards such that the prominence and depression parts 130, 140, 150 and 160 are aligned with each other.

FIG. 6 is a view showing a strip format 300 of a CSP semiconductor package board, according to the second embodiment of the present invention. As shown in the drawing, the second embodiment of the present invention is technically characterized in that rectangular depression parts 320 and rectangular prominence parts 330 are formed in one edge of a dummy area 310 of the strip format 300 of the semiconductor package board. That is, it is to be understood that a portion of the dummy area 300 corresponding to the rectangular depression parts 320 is removed from the dummy area 300.

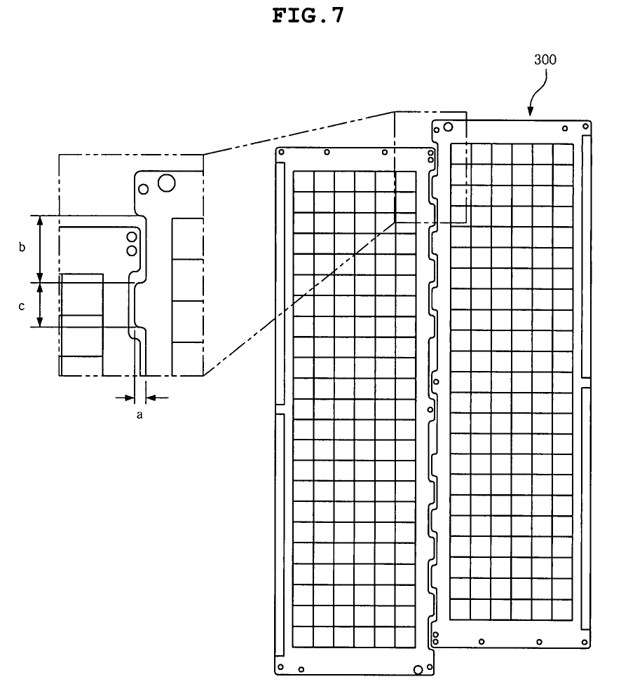

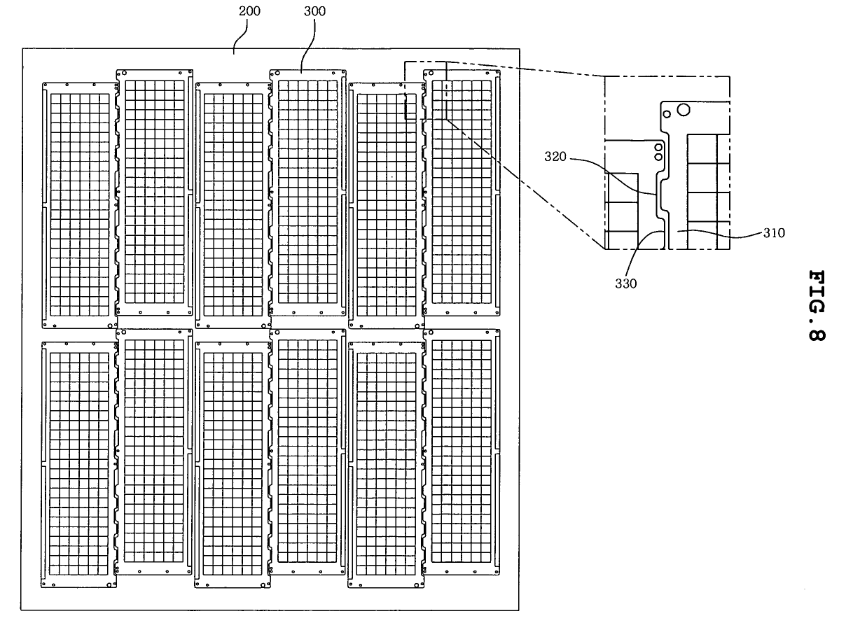

FIG. 7 is a view showing the connection between two strip formats 300 of the semiconductor package boards according to the second embodiments. The dummy area 310 of the strip format 300 according to the second embodiment is formed such that ‘a’ of FIG. 7 is 1.5 mm, ‘b’ is 15, 558 mm, and ‘c’ is 8,758 mm. Here, the standard size of the strip format 300 is 212×63.424, that is, the overall size thereof is not changed. As such, it is appreciated that the above-mentioned object of the present invention can be achieved by forming the dummy area 310 of the strip format 300 of the semiconductor package board into the above shape.

FIG. 8 shows the several strip formats 300 of the semiconductor package boards according to the second embodiment, which are arranged on a panel 200. In FIG. 8, twelve strip formats 300 of the semiconductor package boards are provided on the panel 200. Here, it is to be appreciated that the number of strip formats 300 of the semiconductor package boards is also increased by 20% compared to the conventional art.

Meanwhile, in the two above-mentioned embodiments of the present invention, although it has been illustrated that twelve strip formats of semiconductor package boards can be provided on a single panel, the number of strip formats of semiconductor package boards is not limited to this, and the number thereof may be changed depending on the shape of the dummy area.

As described above, in a strip format of a semiconductor package board according to the present invention, a dummy area is formed into a predetermined shape such that, when several strip formats are arranged on a panel, the number of strip formats arranged on the panel can be increased compared to that of the conventional art, thus enhancing the efficiency of a process of assembling the semiconductor package boards.

Furthermore, the present invention is advantageous in that the coupling relationship between the strip formats is improved because the dummy area of the strip format is formed into the shape disclosed in the present invention. Thereby, there is an advantage in that the error in a manufacturing process is markedly reduced.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A strip format of a semiconductor package board, comprising: a package area, to which a semiconductor device is mounted, with an outer layer circuit pattern formed in the package area; and a dummy area surrounding the package area, wherein
the dummy area is formed into a predetermined shape to improve a coupling relationship between the strip format and another strip format.

2. The strip format of the semiconductor package board as set forth in claim 1, wherein the shape of the dummy area is defined by prominence and depression parts having various shapes such that the strip formats engage each other.

3. A panel array for arranging strip formats of semiconductor package boards, comprising:
a plurality of strip formats of semiconductor package boards, each of the strip formats comprising a package area to which a semiconductor device is mounted, with an outer layer circuit pattern formed in the package area, and a dummy area surrounding the package area and having a predetermined shape; and
a panel, on which the plurality of strip formats of the semiconductor package boards are arranged at regular intervals.

4. The panel array as set forth in claim 3, wherein the shape of the dummy area of each of the strip formats of the semiconductor package boards is defined by prominence and depression parts having various shapes such that the strip formats engage with each other.
